(19) United States
(12) Patent Application Publication
(10) Pub. No.: US 2004/0222082 A1
(43) Pub. Date: Nov. 11, 2004

(54) Oblique ion milling of via metallization

(75) Inventors: Praburam Gopalraja, San Jose, CA (US); Xianmin Tang, San Jose, CA (US); Jianming Fu, Palo Alto, CA (US); Mark A. Perrin, San Jose, CA (US); Jean Yue (Phillip) Wang, Fremont, CA (US); Arvind Sundarrajan, Santa Clara, CA (US); Hong Zhang, Fremont, CA (US); Jick Yu, San Jose, CA (US); Umesh Kelkar, Santa Clara, CA (US); Zheng Xu, Foster City, CA (US); Fusen Chen, Saratoga, CA (US)

Correspondence Address: Applied Materials, Inc., Patent / Legal Department, M/S 2061, P.O. Box 450A, Santa Clara, CA, 95052, US

(73) Assignee: APPLIED MATERIALS, INC.

(21) Appl. No.: 10/429,941

(22) Filed: May 5, 2003

(51) Int. Cl. C23C 14/32; G21G 5/00

(52) U.S. Cl. 204/192.3; 204/192.34; 204/298.26; 204/298.36; 250/492.1

(57) ABSTRACT

In conjunction with sputtering a metal, especially copper, into high aspect-ratio holes in a wafer, an oblique ion milling method in which argon ions or other particles having energies in the range of 200 to 1500 eV are directed to the wafer at between 10 and 35° to the wafer surface to sputter etch material sputter deposited preferentially on the upper corners of the holes. The milling may be performed in the sputter deposition chamber either simultaneously with the deposition or after it or performed afterwards in a separate milling reactor. A plurality of ion sources arranged around the chamber improve angular uniformity or arranged axially improve radial uniformity or vary the angle of incidence. An annular ion source about the chamber axis allows a plasma current loop. Anode layer ion sources and sources composed of copper are advantageous.

### BACKGROUND OF THE INVENTION

1. Field of the Invention

The invention relates generally to sputtering of materials. In particular, the invention relates to the sputter etching of only selected portions of material deposited in and around high aspect-ratio holes.

2. Background Art

Sputtering, alternatively called physical vapor deposition (PVD) in its most common implementation, is widely used to deposit layers of metals and related materials in the fabrication of semiconductor integrated circuits. Typically, a target of the material to be sputtered is placed in opposition to a generally circular wafer to be sputter coated with a material at least partially originating from the target. Electrical means discharge an argon working gas into a plasma, and the resulting positively charged argon ions are attracted to the negatively biased target with enough energy to dislodge (sputter) atom-sized metal particles from the target. Some of these particles travel to the wafer and are deposited in a layer on the wafer surface. In reactive sputtering, a reactive gas, for example, nitrogen, is simultaneously admitted into the sputter reactor. The nitrogen chemically reacts with the sputtered metal atoms to form a metal nitride layer, for example, of tantalum nitride, on the wafer.

Advanced integrated circuits typically include several metallization layers electrically connected by thin vertical vias extending through dielectric layers separating the respective metallization layers. While the lateral dimensions of the vias has decreased to 0.13 μm in advanced commercial devices and will be reduced further in the future, the thickness of the dielectric is constrained by considerations of dielectric discharge and cross talk to be no less than about 0.7 μm, and it may be up to 1.5 μm in some more complex interconnect structures. As a result, the aspect ratio of the via holes into which the metal is to be coated may be 5 and above. The situation is a little more complex in dual-damascene structures, but the trend in the technology is to coat metal into holes of increasingly higher aspect ratio. Sputtering is fundamentally a ballistic process ill suited to penetrating deeply into such holes.

Many advanced integrated circuits use copper metallization because of copper's low resistivity and electromigration compared to aluminum. Copper may be alloyed either intentionally or unintentionally up to 10 wt % with other dopants. A typical copper via structure is illustrated in the cross-sectional view of FIG. 1. A conductive feature 10 is formed in or over a lower-level dielectric layer 12 composed of silicon dioxide, a silicate glass, or a low-k dielectric material. The conductive feature 10 may be a lower-level metallization of copper. The situation is somewhat more complicated if the conductive feature is a semiconducting silicon portion formed in a silicon substrate, but the metallization problems are much the same. An upper-level dielectric 14 is deposited over the lower-level dielectric layer 12 and its conductive feature 10. Patterned oxide etching forms a via hole 16 extending through the upper dielectric layer 14 in the area of the conductive feature. The via hole 16 preferably has a nearly vertical profile and, as mentioned before, its aspect ratio may be 5 or greater. Such etching is available using a plasma formed from a fluorocarbon, such as C₄F₆ and argon, with negative wafer biasing, a process called reactive ion etching.

A barrier is needed on the sides of the via hole 16 to prevent the copper filled into the via hole 16 from diffusing into the oxide dielectric 14 and causing it to short. Also, copper does not stick well to oxide. A thin barrier layer 18 of tantalum nitride (TaN), typically in combination with a Ta layer, serves both purposes. Both layers can be sputter deposited from a tantalum target. Special sputtering techniques are usually employed to allow nearly conformal sputtering onto the sides and bottom of the via hole 16. One such technique called self-ionized plasma (SIP) sputtering, as described by Fu et al. in U.S. Pat. No. 6,290,825, uses a small but strong unbalanced nested magnetron and high target power to produce a relatively high fraction of the sputtered metal atoms that are ionized. The wafer is biased negatively DC, typically from a capacitively coupled RF source, to thereby create a negative self-bias on the wafer adjacent the sputtering plasma. The negative bias draws the positively charged metal ions deep within the via hole. Furthermore, the unbalanced magnetron produces magnetic components which project from the target toward the wafer, thus expanding the plasma and guiding the metal ions toward the wafer. The preferred technique for coating tantalum layers combines the SIP diode sputtering with an RF coil wrapped around the chamber interior to increase the plasma density. However, for sputtering of thin copper layers into vias the straightforward SIP sputtering is often preferred. Either technique is capable of producing relatively thick sidewall 20 and bottom 22 within the hole 16 compared to a thicker field 24 on the planar top of the dielectric layer 24. However, the sidewall 20 tends to vary somewhat in thickness having a thin portion 26 near the center of the sidewall. To assure that the barrier layer 18 covers the entire sidewall 20 to a minimum thickness of a few nanometers, the average sidewall thickness is somewhat more. That is, the barrier sidewalls 20, particularly their top portions, tend to significantly narrow the hole 16 being filled, thus increasing its aspect ratio.

Additionally, the sputtering geometry favors the formation of overhangs 28 at the exposed top comers of the hole 16. Such overhangs 28 significantly increase the effective aspect ratio of the hole during the final stages of the barrier deposition, thus making the uniform sidewall and bottom coverage even more difficult. Furthermore, even if chemical electroplating (ECP) is used to fill the hole with copper, a thin copper seed and electrode layer 30 needs to be coated onto the barrier layer 18, as illustrated in the cross-sectional view of FIG. 1. Sputtering is the favored technique for depositing the seed layer because of its lower cost and generally more favorable surface characteristics relative to copper deposited by chemical vapor deposition (CVD). However, sputtering copper into the via hole 16 partially closed by the barrier overhangs 28 is difficult because of the high effective aspect ratio. Further, sputtered copper tends to form its own overhangs 32 forming a constricted throat 34 so that the final stage of the copper seed deposition is even more difficult and it is possible that the copper overhangs 32 bridge the hole 16 and completely close the throat 34, forming a void within the via hole 16. Even if the via hole 16 remains unbridged at the beginning of the electrochemical plating (ECP) copper fill, the constricted throat 34 presents significant problems to completing the ECP fill. ECP produces a generally conformal coating so that the narrow throat 34 is being filled proportionately faster than the lower, wider portion of the hole 16 and may thus close and create an included void. The effect is exacerbated by the need to replenish the ECP electrolyte within the hole 16 through the rapidly closely throat 34.

The SIP target is generally planar. Shaped targets have been proposed which can produce higher ionization fractions. Gopalraja et al. describe in U.S. Pat. No. 6,451,177 a shaped target having an annular vault facing the wafer. A shaped target having a large cylindrical vault is also known. However, shaped targets are significantly more expensive than planar targets.

Copper metallization is generally used in a dual-damascene interconnect structure, such as that illustrated in cross section in FIG. 3. Narrow vias 40 are formed in the lower half of the dielectric layer 14 to form vertical interconnects. The vias 40 connect to a wider trench 42 formed in the upper half and often extending axially over long distances to form horizontal interconnects as well as to provide pads for a further metallization level. Typically also, the minimum lateral dimension of the trench 42 is wider than that of the vias 40 in a ratio of at least 1.5 and more typically 2.0 or more to facilitate photomask registry. The conductive features 10 in multi-level metallization are typically formed by such a trench 42 in the underlying dielectric layer 12. A single metallization process fills both the vias 40 and the trenches 42. Although the geometry is more complex than the simple via illustrated in FIGS. 1 and 2, overhang and filling problems occur also in dual damascene when a metal layer 44, whether of copper or a barrier material, is sputter deposited. Upper overhangs 46 form adjacent the more exposed comers 48 at the top of the trench 42. On the other hand, at the more protected corners 50 between the top of the vias 40 and the bottom of the trench 42, bevels 52 develop in the deposited layer 44 since the trench sidewalls shield the comers 50 from a substantial portion of the isotropic low-energy ions and neutrals, but high-energy ions preferentially sputter etch the exposed comer geometry.

It is known that increasing the wafer bias during sputtering decreases the field coverage, reduces the overhangs, and increases the bottom and sidewall coverage. The overhangs in particular are preferentially sputtered etched during high-bias sputter deposition in other areas. However, this technique has its limitations. Excessive sputter etching of the comer area can form deep facets at the comer and expose the underlying oxide. That is, the barrier may be removed at the corner, whether in barrier or metallization sputter deposition, a very unfavorable result. Furthermore, excessively high biasing also tends to sputter etch rather than sputter deposit at the bottom of the hole, an effect that needs to be carefully considered.

Rossnagel et al., hereafter Rossnagel, has addressed a related problem in the technical article “Collimated magnetron sputter deposition with grazing angle ion bombardment,” Journal of Vacuum Science and Technology A, vol. 13, no. 1, Jan/Feb 1995, pp. 156-158. Rossnagel faces the problem of voids in filling vias in a collimated sputtering chamber in which the collimator prevents strong biasing effects at the wafer. Instead, he concurrently irradiates the wafer with a beam of energetic argon ions from a Kaufman-type ion source at an angle of 5° to 15° from the horizontal. Rossnagel's apparatus however suffers from the low deposition rates typical of collimated sputtering, and he does not address several problems which would prevent commercialization of his technique. Kaufman sources also suffer from low flux rates.

### SUMMARY OF THE INVENTION

Sputter deposition is combined with oblique sputter etching or ion beam milling. Sputter deposition into a high aspect-ratio hole, such as an integrated circuit via, tends to produce overhangs at the top of the hole. Ion beams inclined at low angles, for example, between 10° and 35° with respect to the substrate surface, strike only the upper portion of the hole sidewall and may be incident upon the major portions of the overhangs at near normal angles. Thereby, the overhang is milled preferentially to lower portions of the hole.

The sputter deposition and ion beam milling may be simultaneously performed. Alternatively, the milling may follow the deposition in the same sputter chamber or in a dedicated milling chamber. Preferably, even for thin copper seed layers, there are multiple cycles of deposition and milling.

The ion beam species may be a inert rare gas, such as argon, or may advantageously be the same metal as that being sputtered, for example, copper for copper metallization, especially copper seed, or tantalum for tantalum-based barrier layer for copper metallization. The beam energy should be relatively high, for example, between 200 eV and 1500 eV, more preferably 400 eV to 1200 eV. The ions in the beam may be neutralized prior to reaching the wafer.

The ion milling may be made directionally uniform about the circumference of a wafer by several means. The wafer may be rotated during milling. Multiple ion sources may be placed around the periphery of the wafer. The ion sources may have a significant azimuthal extent. A single annular ion source may surround the wafer periphery.

Multiple axially arranged ion sources may be used either to more uniformly irradiate across the diameter of the wafer or to adjust between multiple incidence angles. The incidence angle can also be adjusted by magnetic means at the source.

The ion milling may be made more uniform across the wafer by an ion source extending parallel to the chamber axis that is normal to the wafer or by placing multiple ion sources at different heights above the wafer.

The ion source may be an anode layer source in which an anode is included within a surrounding cathode biased negatively to the anode. A gap or slit is formed in the cathode opposite the anode. Preferably, the anode and cathode are composed of the material being sputter coated onto the substrate, for example, copper. A magnetic field is preferably imposed in the region between the anode and cathode, for example, from a permanent or one or more electromagnets disposed in back of the anode with respect to the gap or disposed outside of the cathode cell. Optionally, a biased grid may be disposed outside of the gap. The gap may be formed in the shape of a racetrack or in an annulus surrounding the chamber axis, thereby allowing a plasma ring to develop.

### BRIEF DESCRIPTION OF THE DRAWINGS

FIGS. 1 and 2 are cross-sectional views of a conventional via coating process in which overhangs develop.

FIG. 3 is a cross-sectional view of a conventional dual-damascene structure including overhangs and bevels which can develop.

FIG. 4 is a cross-sectional view of a sputter reactor incorporating one embodiment of the invention.

FIG. 5 is a cross-sectional view show the selective milling of overhangs by an oblique ion beam.

FIG. 6 is a graph showing the angular dependence of the fractional depth that obliquely directed ions reach into a narrow hole.

FIG. 7 is a graph showing the angular dependence of sputter etching by energetic ions.

FIG. 8 is a plan view of a chamber having a plurality of ion sources distributed along its wall and about its central axis.

FIG. 9 is a plan view of a chamber having azimuthally extended ion sources.

FIG. 10 is a plan view of a chamber having an annular ion source.

FIG. 11 is a cross-sectional view of part of a sputter reactor including the pedestal, shields, and annular ion source.

FIG. 12 is cross sectional view of a chamber having multiple ion sources distributed axially in the chamber wall and irradiating different radial portions of the wafer.

FIG. 13 is a cross section view of a chamber having multiple ion sources producing beams inclined at different angles with respect to the wafer.

FIG. 14 is a plan view of an ion source having an emission port in the shape of a racetrack.

FIG. 15 is a schematic cross-sectional view of a single-slit anode layer ion source (ALS).

FIG. 16 is a schematic cross-sectional view of a double-slit ALS.

FIG. 17 is a schematic cross-sectional view of a first embodiment of a magnetically enhanced ion source.

FIG. 18 is a schematic cross-sectional view of second embodiment of a magnetically ion source.

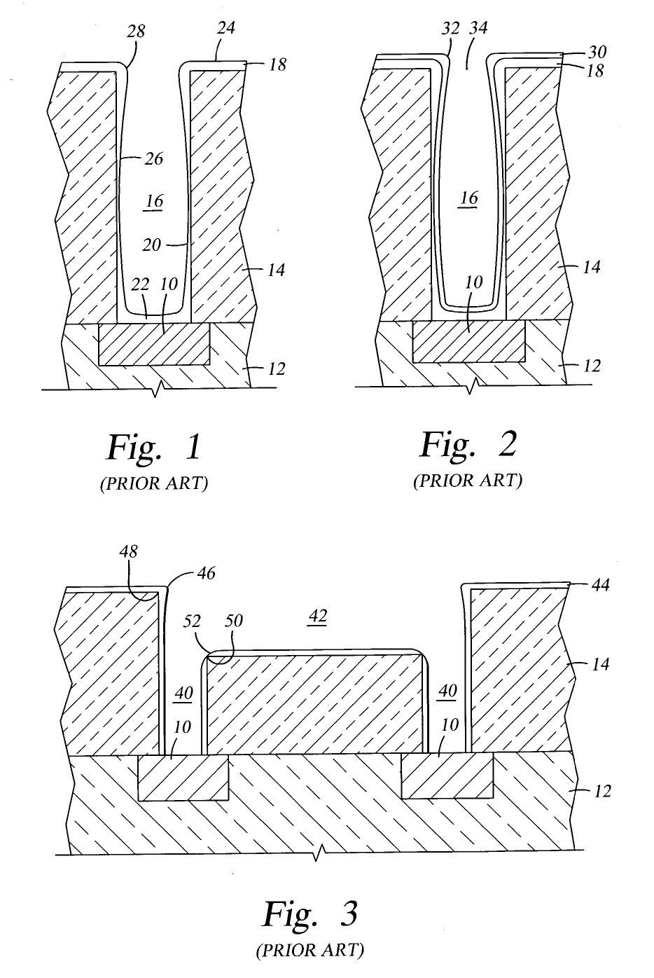

FIG. 17 is a schematic cross-sectional view of a copper hollow anode ion source.

### DETAILED DESCRIPTION OF THE PREFERRED EMBODIMENTS

Oblique ion beam sputter etching can be combined with biased sputter deposition to more uniformly coat the sidewalls of via and other holes having very high aspect ratios. The combination reduces the overhangs and prevent the overhangs from closing the hole and creating voids in the via metallization. The beam ions have sufficient energy, for example, 200 eV and higher, such that material is sputter etched rather than sputter deposited from the wafer, particularly for the exposed comers. Further, it is preferred that ion sources be used which have high fluxes and whose exposed parts are not composed of magnetic materials but instead be formed of the barrier or seed material, that is, tantalum or copper, in order to avoid contamination.

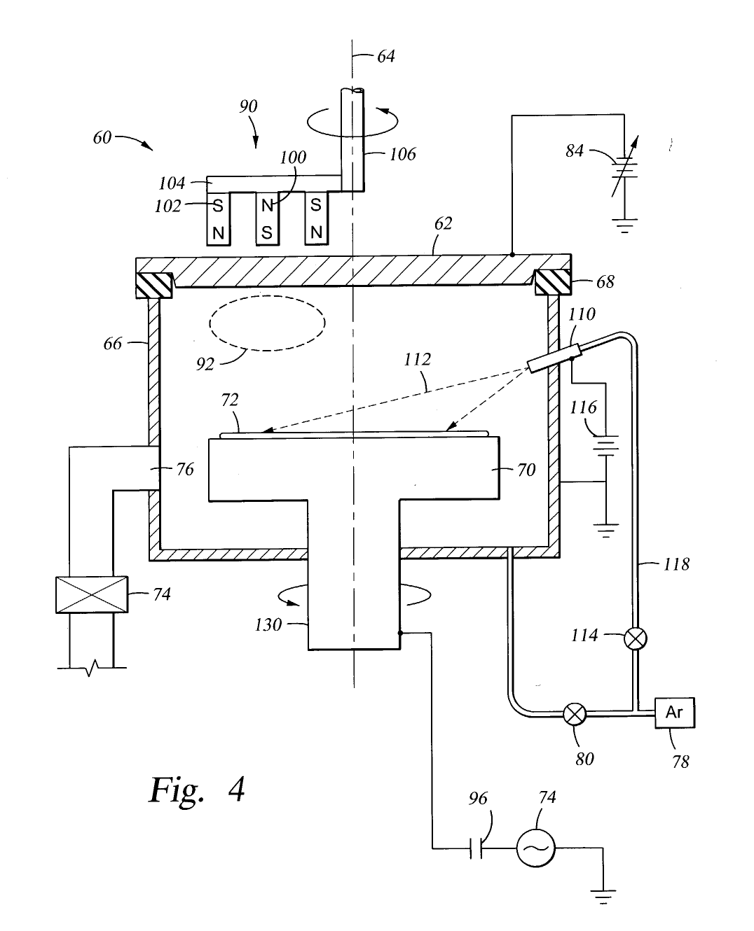

A plasma sputter reactor 60 illustrated in FIG. 4 is based upon a self-ionized plasma (SIP) reactor available from Applied Materials. It includes a planar target 62 arranged about a central axis 64 and supported on a grounded chamber body 66 through an annular isolator 68. At least the surface portion of the target 62 is composed of the material to be sputtered, but copper targets are typically fabricated of solid copper. A pedestal electrode 70 supports a wafer 72 to be sputter coated in opposition to the target 62 along the central axis 64 and includes unillustrated chilling fluid lines and thermal transfer gas cavities for controlling the wafer temperature. Unillustrated shields, at least one of which is typically grounded, protect the chamber walls from deposition and also serve as the anode against the cathode of the negatively biased target 62. A vacuum system 74 pumps the vacuum chamber through a pumping port 76 to a base pressure of less than 10⁻⁶ torr. However, a sputter working gas, typically argon, is supplied from a gas source 78 through a mass flow controller 80 into the chamber. The argon is maintained in the chamber at a few milliTorr for plasma ignition, but for sputtering copper in an SIP reactor the chamber pressure may be reduced to well below 1 milliTorr after ignition.

A controllable DC power supply 84 negatively biases the target 62 to about −400 to −800VDC to excite the argon into a plasma and to maintain it in the plasma state. The positively charged argon ions are accelerated toward the negatively biased target 62 and sputter metal atoms from it. Some of the metal atoms strike the wafer 72 and coat it with a metal layer. In reactive sputtering, a reactive gas such as nitrogen, is also admitted into the chamber. The nitrogen reacts with the sputtered metal atoms, for example, tantalum, to form tantalum nitride. Tantalum and tantalum nitride are commonly used as barrier materials between oxide and copper.

A magnetron 90 is positioned in back of the target 62 to produce a magnetic field inside the chamber adjacent the target surface. The magnetic field traps electrons and thus increases the plasma density to form a region 92 of a high-density plasma. The high-density plasma not only increases the sputtering rate but also causes a significant fraction of the sputtered atoms to be ionized. The density of the plasma is increased by a high power level to the target 62 and is further increased by the small magnetron 90 concentrating the sputtering power to a small area of the target 62. Sputtered ions are accelerated to the wafer 72 when an RF power supply 94 coupled to the pedestal electrode 70 through a capacitive coupling circuit 96 induces a negative DC self bias on the pedestal electrode 70 as it interacts with plasma. Even in the absence of RF bias power, a floating electrode will develop a negative bias of about 50 to 60VDC. A high metal ionization fraction also causes some of the metal ions to be attracted back to the target 62 and induce further sputtering, that is, to effect self-ionized sputtering, thereby allowing a plasma to be supported at reduced argon pressure. In the case of copper in a properly designed and operated plasma sputter reactor, the argon supply may be discontinued after the plasma is excited so that the chamber pressure can be reduced to less than 0.2 milliTorr.

In an SIP reactor, the ionization effect is increased by the magnetron 90 being small, nested, and unbalanced. An inner pole 100 of one vertical magnetic polarity is surrounded by an annular outer pole 10 of the opposite magnetic polarity. A magnetic yoke 104 supports and magnetically couples the two poles 100, 102. The total magnetic intensity of the outer pole 102 is substantially larger than that of the inner pole 100 in a ratio of at least 1.5 and preferably 2.0 or more. The unbalanced magnetic field from the outer pole 102 produces a magnetic field component which projects towards the wafer 72, both extending the plasma, supporting a plasma at reduced chamber pressure, and guiding the sputtered metal ions toward the wafer 72. Unillustrated auxiliary magnets on the side of the chamber 66 may be used to further shape the magnetic field. The magnetron 90 has a fairly small size and is, for the most part, disposed away from the central axis. To provide more uniform sputtering, the magnetron 90 is supported on and rotated by a rotary drive shaft 106 extending along the central axis 64. No collimator is required since the somewhat axial magnetic field projecting from the unbalanced magnetron 90 provides some guiding and focusing towards the wafer 72.

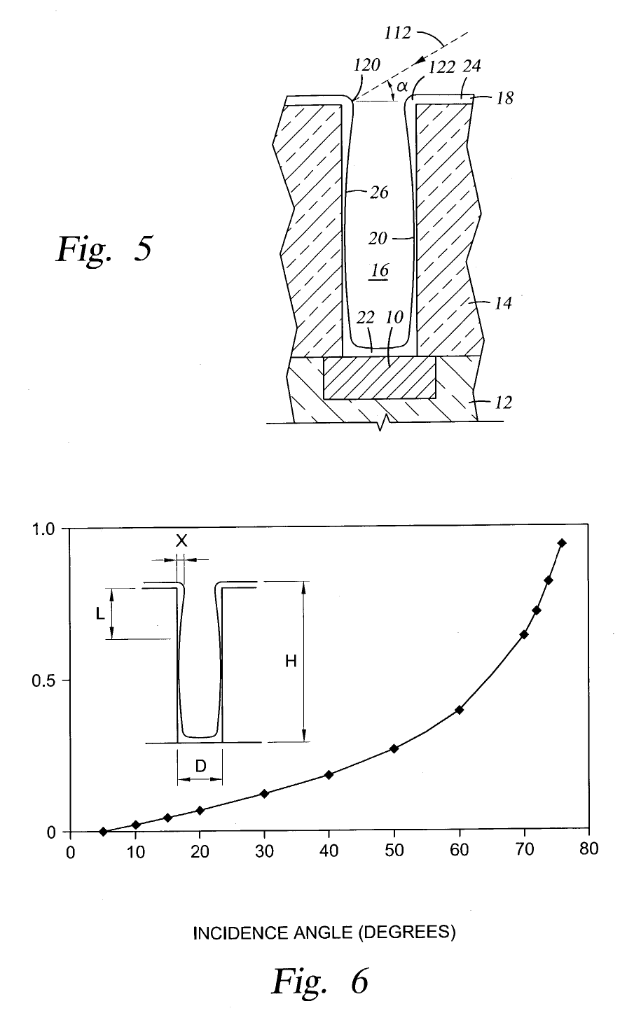

According to one aspect of the invention, an ion source 110 is located to the side of the pedestal electrode 70 and produces an ion beam 112 that obliquely strikes the wafer 72 at a beam angle α of between 10° and 35° with respect to the perpendicular from the central axis 64, that is, at a small oblique angle with respect to the wafer surface. Even smaller angles may be used in particular applications but a 20° to 30° angle is often preferable for a single incidence angle. It is understood that the ion beam 112 may be partially or fully neutralized prior to reaching the wafer 72, but apart from wafer biasing effects the neutral beam atoms are equally effective at milling exposed material. The design of the ion source 110 is open to some choice, but one type includes the supply of argon from the gas source 78 through a separate mass flow controller 114 and a controllable DC power supply 116 through a supply line 118 to the ion source 110. As shown in the cross-sectional view of FIG. 5, the ion beam 112 arrives at the top of the via hole 16 at the small angle α. Its energetic ions strike a far overhang 120 at a nearly perpendicular angle but more typically at 70° to 80° for most of surface of the overhang 120. However, they barely graze a near overhang 122, and they strike the field area on top of the dielectric layer 14 at the small angle a, angles typically producing much low sputter etching. Further, in a high aspect-ratio hole, the energetic ions strike only near the top of the sidewall and are shielded form lower portions of the sidewall. In a simple model of a cylindrical hole having a sidewall depth D, a width W, and thus an aspect ratio AR=W/D, the obliquely incident ion strikes only a fraction

$$\frac{tan α}{AR}$$

of the sidewall length D at its upper portion. Assuming an aspect ratio AR of six, a beam having a beam angle α of between 10° and 30° strikes only the upper 3 to 10% of the sidewall. The dependence of the fractional depth versus incident angle is plotted in FIG. 6 for a different model in which the maximum depth reached by the oblique beam is L, the hole diameter d is 0.13 μm, the aspect ratio is 4:1, and the overhang projects a distance x from the sidewall by 10% of the hole depth H. The oblique ion milling of the overhang provides a further advantage that further increasing the ion incident angle enables the atoms sputtered from the overhang 120 to be ejected downwardly into the via hole 16 rather than upwardly. As a result, the ion milling may act to deposit additional material on the via sidewall. The energy and intensity of the ion beam may be varied during the sputter deposition period as the hole geometry is changing.

The sidewall selectivity is more complex with the dual-damascene structure illustrated in FIG. 3, which emphasizes the longitudinal extent of the trench 42 rather than its width. In the illustrated structure, substantially all of the trench sidewall is subjected to ion milling with a ion beam inclined at about 20°. Nonetheless, any overhang at the upper corner 46 is subject to increased sputter etching. Furthermore, the lower comers 50 are not exposed to head-on ion milling unless there is an intermediate via 40 between the two illustrated ones or if the trench 42 represents a large contact pad. However, the situation differs in the cross section transverse to the trench axis, that is, along the trench width, since the trench 42 has a much larger effective aspect ratio along the trench width than along the trench length so that some selective ion milling of the upper trench sidewall is obtained. In typical applications, there is some angular averaging between the length and width directions of the trench since angular uniformity is needed, whether provided by an annular or azimuthally distributed source or by rotating the wafer.

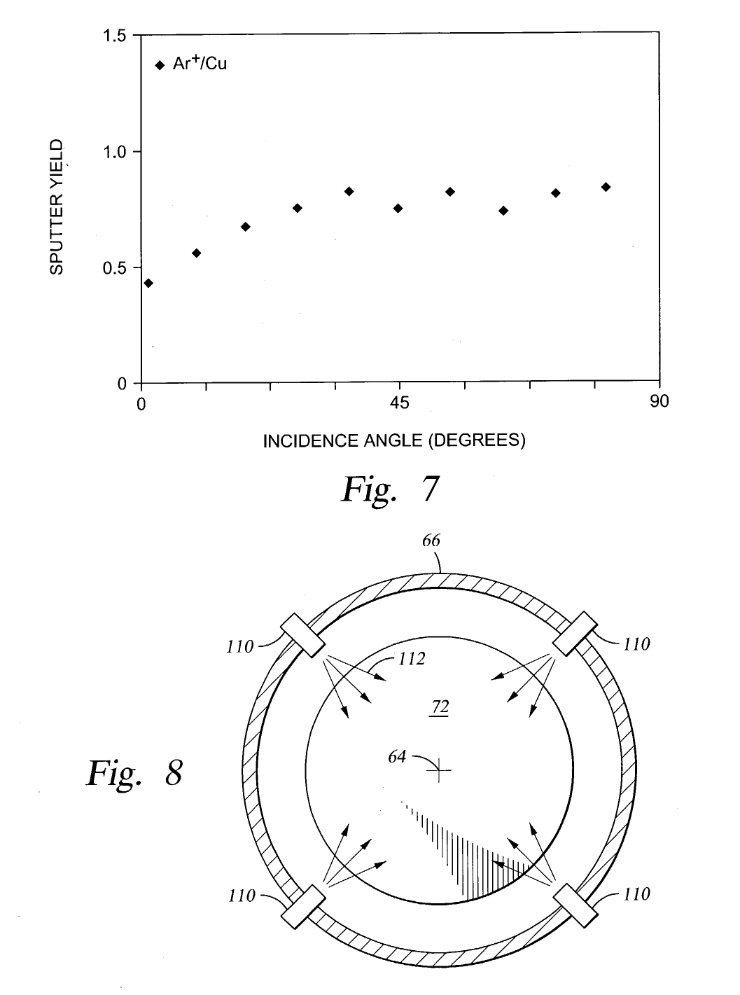

The sputter yield is plotted in FIG. 7 for argon ions incident upon a copper surface as a function of the ion incidence angle, that is, the angle between the direction of the ion beam and the plane of the surface. The sputter etching is reduced for low incidence angles below 30°. Although the simulations were performed for 100 eV ions, the same trend is expected in the range of interest between 100 eV and 5 keV.

Oblique ion milling is clearly asymmetric between the sidewalls of the hole because of the differing incidence angles with respect to the local surfaces. In order to achieve a more uniform milling of the overhangs, the wafer pedestal 70, as shown in FIG. 4, may be supported on a rotary drive shaft 130 extending along the central chamber axis 64. The drive shaft 130 may be coupled to an external motor through a rotary vacuum seal, magnetic coupling, or other vacuum drive means. The drive shaft 130 rotates the wafer 72 at a constant angular rate at least one and preferably a large number of revolutions during the ion milling procedure. Thereby, all sides of the hole and associated overhangs are exposed to a more symmetric time-averaged flux of high-energy ions.

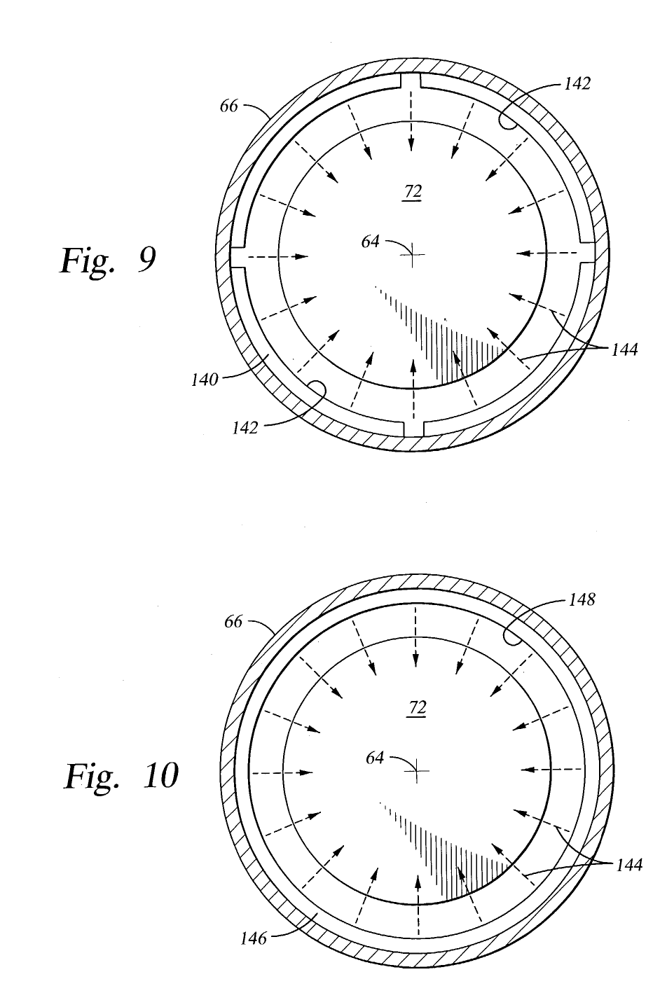

To avoid the difficulties of rotating the pedestal in a high-vacuum plasma sputter reactor, more uniform ion milling in the azimuthal direction can be alternatively achieved with a stationary pedestal 70 supporting the wafer 72, as illustrated in the plan view of FIG. 8, by positioning a plurality of ion sources 110 around the periphery of the chamber wall, all facing the wafer 72 and the central axis 64. Preferably, four ion sources 110 are arranged at 90° intervals and aligned with the typically rectilinear interconnect patterning of the wafer. Additionally, as illustrated in the plan view of FIG. 9, azimuthally distributed ion sources 140 having curved emission fronts 142 centered about the axis 64 are positioned mostly inside the chamber wall 66. The emission fronts 142 are relatively wide, preferably filling at least 180° around the center axis 64, to produce radial ion beams 144 covering an increased fraction of the total wafer circumference. The number of distributed sources 140 may be two, three, four as illustrated, or even more.

Alternatively, a single annular ion source 146, illustrated in plan view in FIG. 10 has a circular emission front 148 about the center axis 64 so that its radial beams 144 produce an azimuthally uniform ion flux on the wafer 72. Despite its fabrication difficulties, the single annular structure presents substantial advantages for many of the ion sources to be described later. In particular, a plasma ring current can be created to circle the chamber axis 64.

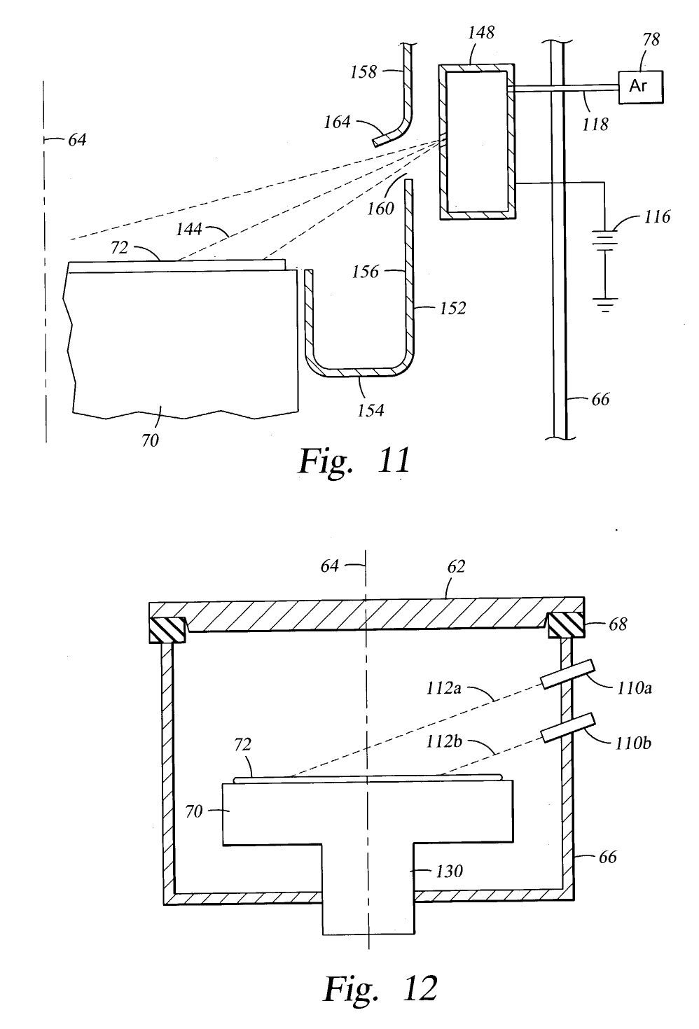

The annular ion source 148 requires addressing of the problem with the chamber shields. A primary shield typically used in a plasma sputter reactor protects the walls 66 and side of the pedestal 70, as illustrated in the schematic cross-sectional view of FIG. 11, from sputter deposition. Additionally, it is typically grounded to act as anode in opposition to the target. Unillustrated auxiliary shields may be used for other purposes. When the shields instead of the wall and pedestal are coated with extraneous deposition, the shields are replaced so that cleaning of the larger chamber parts is not required at that time. The typical primary shield includes an cylindrical portion 152 extending along the chamber sidewall 66 to in back of the pedestal support surface to protect the chamber sidewall 66. An annular cup portion 154 bends back up on the side of the pedestal 70 to protect the chamber bottom wall and the side of the pedestal 70.

The oblique ion source needs to penetrate the sidewall shield and not significantly degrade the shielding function. Accordingly, the primary shield is divided into a bottom shield 156 and a top shield 158, both of which are grounded. An annular gap 160 separates the bottom and top shields 156, 158. The annular ion source 148 is positioned between the shields 156, 158 and the chamber wall 66. Its emission slit 162 is positioned in back of the shield gap 160. The ion source 148 is designed to emit its radial beams 144 at a small oblique angle a with respect to the surface of the wafer 72 but with a substantial beam spread. The upper shield 158 may include at its lower end an inwardly and downwardly extending lip 164 to block any line of sight from the target through the shield gap 160, thus protecting the ion source 148 from being sputter coated. The ion source 148 is powered by the power source 116 and receives argon from the supply line 118. The mechanical support for the bottom shield 156 and the ion source 148 is not shown but may be easily provided. If the ion source is not annular, a single primary shield with a number of localized gaps corresponding to the number of more localized sources may be used to the same effect.

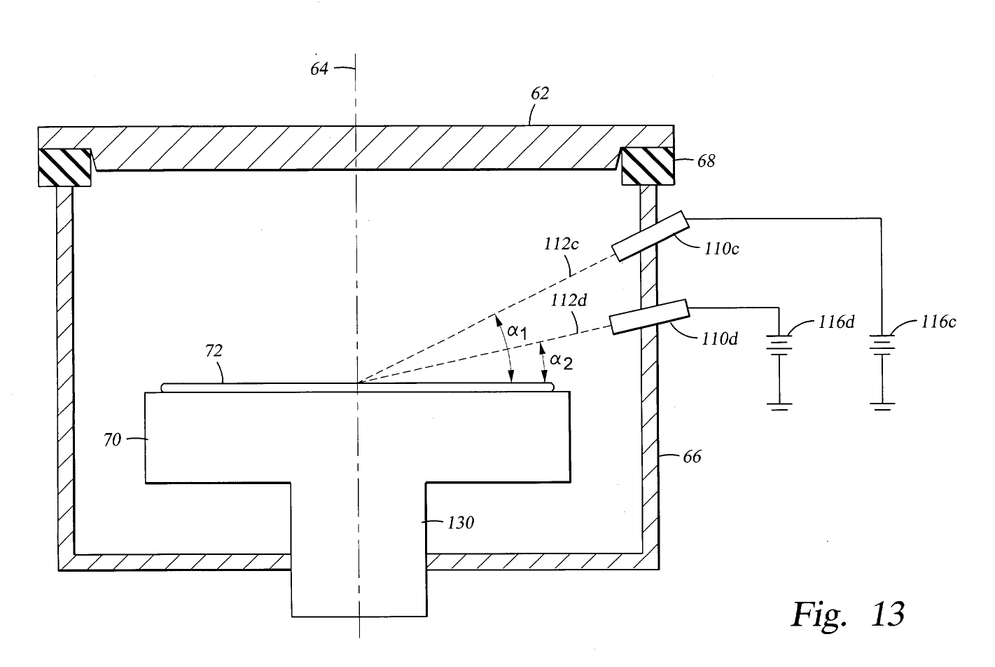

As should be evident from FIG. 4, the limited space within the vacuum chamber requires the ion sources be placed relatively close to the edge of the wafer 72 and thus introduces an asymmetry in incidence angle between the portions of the ion beam 112 reaching the near side of the wafer 72 and those reaching the far side. Associated with the polar angular asymmetry is an intensity asymmetry arising from the different beam lengths and angular positions with respect to the beam center line. These asymmetries can be reduced by using multiple ranks of ion sources 110a, 110b, as illustrated in FIG. 12, spaced along the chamber axis 64. They may be inclined at the same angle α with respect to the wafer surface but axially positioned such that the central portion of the two beams 112a, 112b strike opposite sides of the wafer 72 with respect to the central axis 64 but at the same inclination angle. The intensity asymmetry can be reduced is the two ion sources are sized differently or have separately controlled power supplies such that the upper source 110a produces a more intense ion beam than the lower source 110b. If the ion sources 110a, 110b are positioned on only one side of the chamber as illustrated, a sidewall asymmetry persists between the near and far sidewalls of the hole being etched. The sidewall asymmetry is reduced by rotating the pedestal 70, as in FIG. 4, or by the multiple or distributed ion sources 110, 140, 147 of FIGS. 8, 9, and 10. If the pedestal 70 rotates, the two ion sources 110a, 110b may be placed at different azimuthal positions in the chamber wall 66 around the central axis 64.

As should be evident from FIG. 6 and the associated discussion, the selective sidewall ion milling depends geometrically upon both the aspect ratio of the hole and the angle α of the beam. While the incidence angle can be optimized for a particular aspect ratio, it is disadvantageous to need to redesign a sputter reactor with a new ion source for a new type of hole geometry. It is instead advantageous that the sputter reactor, as illustrated in FIG. 13 include multiple, independently operated ion sources 110c, 110d producing respective ion beams 112c, 112d inclined at different incidence angles α₁, α₂, for example, one nearer 10°, the other nearer 35°. The energies of the two beams 112c, 112d may differ. The two ion sources 110c, 110d may be independently powered by two controllable power sources 116c, 116d so that a controlled amount of one or both beams 112c, 112d mills the wafer 72. Alternatively, the two sources 110c, 110d may be alternatively pulsed to provide the effect of rocking the ion beam. Beam rocking could be achieved by rocking the pedestal 70 or by rocking one ion source. However, the electronic rocking afforded by two ion sources 110c, 110d is considered superior. Yet further, it may be advantageous to vary the relative intensities of the two beams 112c, 112d as the sputter deposition progresses. The two beams 112c, 112d are illustrated in FIG. 13 as having beam centers coincident at a same point on the wafer 72. Such coincidence is not required.

It is understood that the ion source configurations of FIGS. 12 and 13 are somewhat conceptual. The drive shaft 130 may rotate the pedestal 70, as described with reference to FIG. 4, and the pairs of sources 110a, 110b or 110c, 110d may be azimuthally displaced. There may be multiple ones of the two sources 110a, 110b or 110c, 110d distributed about the chamber azimuth, or more advantageously the two sources 110a, 110b or 110c, 110d may each be annular sources.

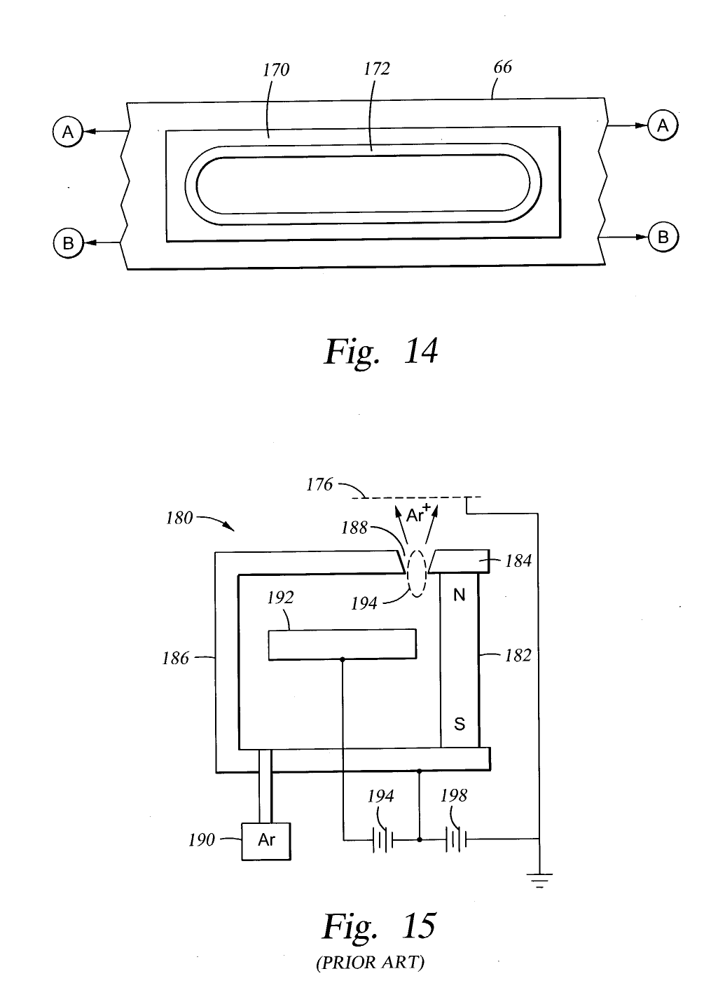

Several of the ion sources which will be described later in more detail emit along a linear emission port extending perpendicularly to the axis of the ion beam. The linear extent can be arranged axially, accounting for the polar beam angle α, to achieve the axial distribution of FIG. 12, or azimuthally, to achieve the circumferential distribution of FIGS. 9 and 10. One conventional type of ion source can be adapted to form an ion source 170, illustrated in the outwardly facing circular elevation of FIG. 14, attached to the inner surface of the tubular chamber wall 66. The ion source 170 has a racetrack shape emission port 172 which has two parallel portions spaced apart along the chamber axis 64 and joined by curved end portions. A single such ion source 170 can be wrapped around substantially the entire chamber periphery or multiple such ion sources 170 may be spaced about the chamber periphery. In either case, such a configuration provides both an axial and an azimuthal distribution of the emitted beams. Such a design can be extended to multiple wraps along the chamber axis.

The different types of ion sources can be operated in several different modes. Again in reference to FIG. 4, although it is understood that different types and numbers of ion sources may be substituted, the ion milling can proceed simultaneously with the sputter deposition. For sputtering into high-aspect ratio holes, the RF bias source 74 biases the pedestal electrode 70 to about −80 to −100VDC, thereby accelerating the sputtered copper ions across the plasma sheath into the narrow hole. If the plasma extends near the wafer 72, the oblique beam ions are subject to the same acceleration as the copper ions, which would increase their inclination angle. However, such electrostatic bending tends not be a large effect for two reasons. The ion beam is mostly neutralized by charge exchange interactions and thus not electrostatically bent. Furthermore, the plasma sheath is mostly restricted to the high plasma-density region 92 located away from the ion beam 112. Even so, if the ion energy is maintain at 200 eV and above, the bending angle can be minimized so that the sputter ions enter the narrow holes perpendicular to the plane of the wafer but the beam ions strike the hole at a small oblique angle. The beam ions are also subject to the same projecting magnetic fields from the unbalanced magnetron 90 as are the sputter ions. However, the fields close to the wafer are generally below 20 gauss, which at the significant energies contemplated for the beam ions do not cause undue deflection. A neutralized beam is not affected by the magnetic field.

It is appreciated that the amount of wafer biasing provided by the RF bias source 74 can be reduced if oblique ion milling is employed. A more isotropic lower-energy copper flux is allowed to grow the overhangs with much reduced concern about beveling on one hand and bridging on the other hand since the overhangs are being removed by the ion milling.

Alternatively, the ionized sputter deposition and the ion milling can be alternately performed in the same sputter reactor. This process preferably includes multiple cycles of a phase of sputter deposition and a phase of ion milling. In a first phase, the ion source is turned off, and sputter deposition is performed under moderate biasing until a significant overhang develops. In a second phase, the bias power is turned off, the pedestal electrode 70 is either grounded or left floating, and the ion source is turned on to mill the overhang. The target power could be turned off in this phase, but this would require reigniting the plasma afterwards. Instead, the target power can be turned down to reduce sputter deposition but not enough to extinguish the plasma. Although only a single cycle may be used in a post in-situ process to remove any overhang that has developed, it is better to use multiple cycles even in depositing a thin layer so that the overhang does not develop to the point that it shadows the concurrent sputter deposition. For copper seed deposited at a blanket rate of about 5 nm/s, one to five seconds of sputter deposition may be followed by approximately the same length of ion milling and three to five cycles of deposition and milling should be enough for 5 nm sidewall coverage on vias and trenches.

The chamber design can be greatly simplified if a separate reactor apart from the sputter deposition reactor is used for the ion milling. That is, after deposition of the thin layer complete with significant overhangs in a conventional plasma sputter reactor, the wafer is transferred to an ion milling chamber which lacks any ability for sputtering. Not only are the target, the magnetron, and the sputtering power supplies not needed, the sputtering shields may be eliminated and the chamber base line pressure may be considerably higher, thus simplifying the design for a rotatable pedestal. The ion milling chamber may be attached to a common transfer chamber to minimize oxidation of the sputtered metal layer. However, before electrochemical plating, a moderate amount of oxidation of the copper can be tolerated so the milling chamber for a single post mill need not be vacuum protected. However, if a separate ion milling chamber is used for removing overhangs, it is preferred that the barrier deposition chamber, the ion milling chamber, and the copper seed chamber all be connected to a common transfer chamber or integrated processing tool such as the Endura platform available from Applied Materials.

The chamber pressure should be minimized during the ion milling to maintain the directionality of the ion beam and the beam energy. The mean free path of a 400 eV argon ion is 4.8 cm at an argon pressure of 1 milliTorr based upon charge transfer cross sections, and the mean free path is inversely proportional to pressure. The corresponding values for helium and neon are 13.1 cm and 9.5 cm. These values need to be compared with the wafer diameter plus the space occupied by the shields. Chamber pressures of 0.1 milliTorr are achievable with copper sputtering. Both the charge transfer and momentum transfer cross sections are substantially constant above 200 eV but increase substantially at lower energies.

It is thus preferred to maintain an ion energy of at least 200 eV and preferably 400 eV and above. Energies above 1200 eV introduce complexities into the source design and may cause damage in the wafer. It is believed that an energy of 400 to 500 eV is satisfactory.

Obliquely directed ion beams can also be effectively used for smoothing films and performing other surface modifications.

Both gridded and gridless ion sources can be used. is they demonstrate good reliability and ease of maintenance in nearly continuous use. Compared with simple DC gridded ion source, RF-based gridded sources offer advances of less required maintenance in the presence of reactive gases. The RF powering may be achieved through inductive coupling, capacitive coupling, or microwaves. On the other hand, gridless ion sources such as end-Hall and closed-drift ion sources are finding increased applications as broad-beam ion sources. The end-Hall source is named because the beam exits the acceleration region at the end axis of the magnetic field. In the close-drift source, the ion acceleration channel is annular, rather than circular as in the end-Hall source. Two types of closed-drift ion sources are distinguished according to the electrical potential variation throughout the acceleration region. The two are a magnetically layered ion source and an anode layer ion source. Since ions are generated in these source over an extended region with varying potential, these sources typically exhibit high ion flux and a wide range of ion energies, typically ±30% of the mean ion energy.

Several types of ion sources adaptable for use with the invention are commercially available from Advanced Energy and Veeco, both of Fort Collins, Colo. For example, a single-slit anode layer ion source (ALS) 180 is illustrated in schematic cross section in FIG. 15. A cell wall is formed by a permanent magnet 182 and two magnetic and conductive wall sections 184, 186 with a gap 188 between the two wall sections 184, 186. An argon gas source 190 supplies a controlled amount of argon into the cell although, when used in sputter reactor, there may be sufficient back flow of argon from the reactor through the gap 188 into the cell to dispense with the separate argon supply. The inner and outer wall sections 184, 186 abut opposite ends of the magnet 182 and act as a magnetic yoke focusing the magnetic field across the gap 188. An anode 192 is positioned within the cell generally in opposition to the gap 188, and a DC power supply 194 biases it negatively to the two wall sections 184, 186, thus acting as inner and outer cathodes, to discharge the argon into a plasma 194 including argon ions Ar⁺. In one mode of operation, the negatively biased cathodes 184, 186 accelerate the ions out of the cell through the gap 188. An optional grid 176 positioned in front of the gap 188 is biased negatively by a second DC power source 198 with respect to the cathodes 184, 186 to further accelerate the argon ions.

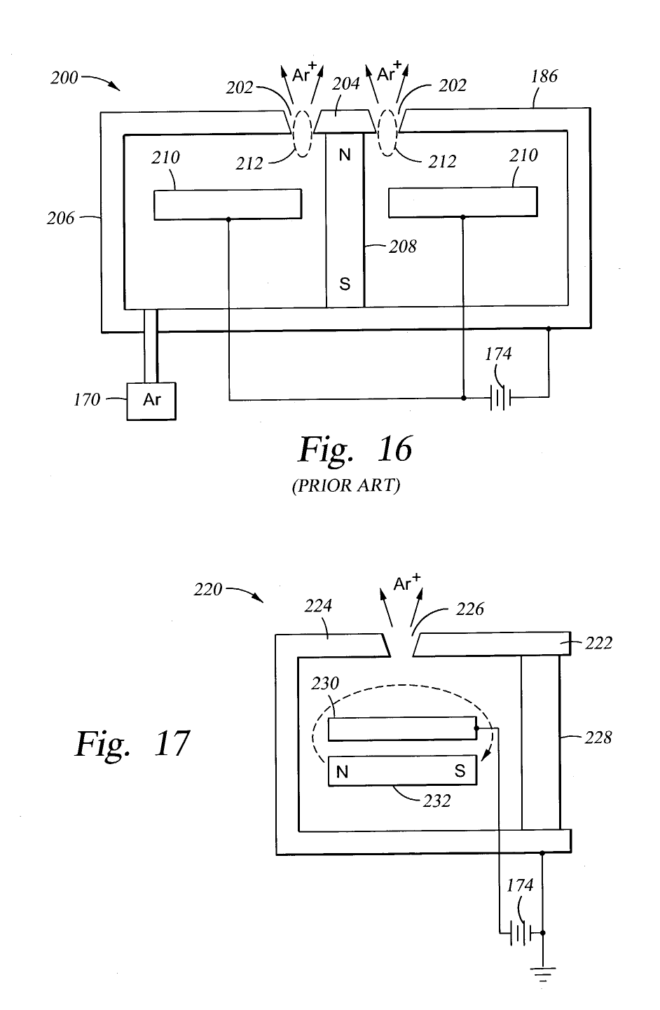

A two-slit anode ALS 200 illustrated in FIG. 16 includes two linearly extending slits 202 between inner and outer magnetic cathodes 204, 206. The slits 202 are separated by the inner cathode 204 and are connected out of the plane of the illustration around the ends of a magnet 208 in a racetrack configuration. Two anodes 210 are disposed on the sides of the magnet 208 generally in opposition to the slits 202 and may also extend around the ends of the magnet 208 to connect with each other. As a result, a ring shaped plasma region 212 is formed near and below the slits 202. A magnetic field extends generally horizontally across the slits 202 and an electric field extends generally vertically between the cathodes 204, 206 and the anode 210. The resultant E×H force produces a strong continuous Hall current J_{H} along the racetrack-shaped slit 202. Typically, the width of the slits 202 is a few times the electron cyclotron radius. The argon ions in the slits 202 will be accelerated quickly out of the discharge cell by the strong potential variation with no collisional loss because the discharge channel length is small than the ion cyclotron radius. As a result, even if the ions are neutralized, a high energy has been imparted to them. Much the same effect can be achieved with the single-slit ion source 180 of FIG. 15 if it is formed as a single annular ion source extending around a circumference of the chamber wall, thus allowing a ring current to develop in the annular plasma region.

The conventional ALS ion sources 180, 200, however, require cell walls to be composed of magnetic material. Magnetic materials should be avoided in direct contact with plasma of a semiconductor processing chamber since even trace amounts of magnetic and other heavy metal contaminants cause serious reliability problems in the fabricated circuits. A copper ALS ion source 220 illustrated in FIG. 17 includes copper inner and outer cathodes 222, 224 with a gap or slit 226 between them. The cathodes 222, 224 and a spacer 228 made of a dielectric for magnetic field purposes define a cell chamber in which is placed a copper anode 230. Argon may be supplied from an unillustrated separate source or may back flow from the reactor. The DC voltage source 174 biases the copper anode 230 positively with respect to the cathodes 222, 224. A magnet 232 is disposed inside the cell chamber on the opposite side of the anode 230 from the slit 226. It is horizontally polarized so that it creates a substantially horizontal magnetic field in the area between the anode 230 and the cathode slit 226. The magnet 232 acts as a magnetron increasing the plasma density to thereby increase the argon ion flux out of the cell through the slit 226. If the plasma density is raised high enough, the copper cathodes 222, 224 act as plasma sputter targets and a substantial fraction of the sputter copper is ionized to generate copper ions to produce a copper ion beam. The cathodes 222, 224 further act as an extraction electrode such that the argon or copper ions are emitted through the slit 226.

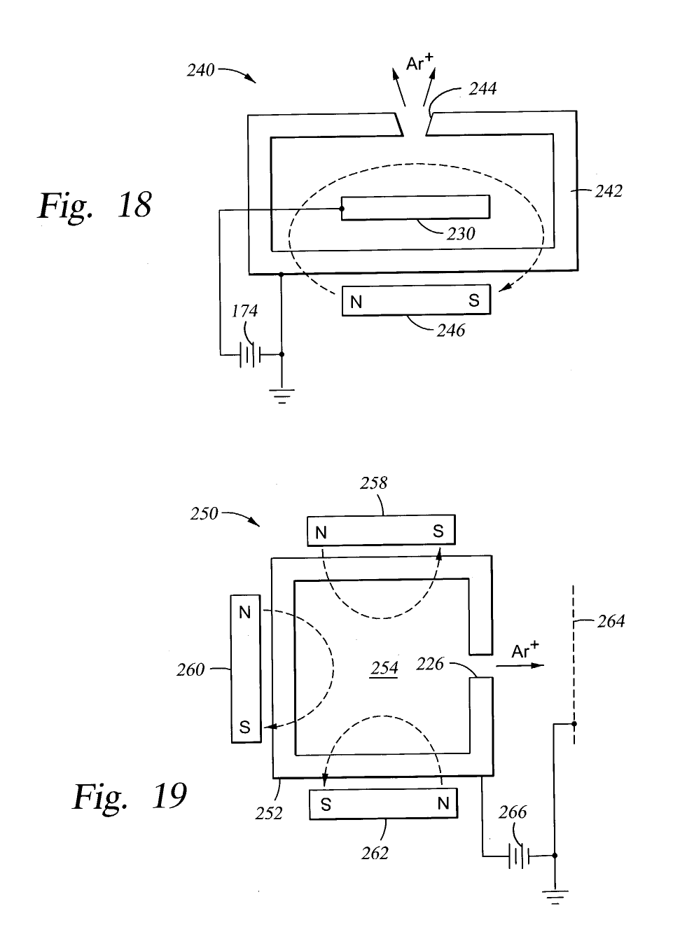

An ion source 240 illustrated in FIG. 18 is similar except that the cell wall is formed of a single copper cathode 242 with a slit 244 formed in one side in opposition to the anode 230. A horizontally polarized magnet 246 is positioned outside the cell chamber in back of the anode 230 with respect to the slit 214. The magnet 246 may be a permanent magnet or one or more electromagnets. The multiple electromagnets can be separated powered to control the position of the high density plasma along the cathode 230 facing the exit slit 244. Thereby, the angle of the beam may be electrically controlled. Similar angular control can be applied to the magnet 232 of FIG. 17.

A copper hollow cathode magnetron ion source 250 illustrated in FIG. 19 includes a copper chamber 252 enclosing a cell interior 254. A slit 256 is formed in one of the walls of the chamber 252. Magnets 258, 260, 262 are disposed on the outside of three walls of the chamber 252 to create a magnetic field along the respective walls on the cell interior 254, which increases the density of a plasma formed in cell interior 254. If the magnets 258, 260, 262 are separately controlled electromagnets, the position of the plasma along the wall 252 may be controlled, thus controlling beam direction. An extraction grid 264 is positioned outside the chamber interior 254 in opposition to the slit 256. A DC power source 266 biases the grid 264 negatively with respect to the chamber 252 to extract argon or possibly copper ions from the cell interior 224.

It is appreciated that when tantalum or other refractory metal is being sputtered, it is advantageous to have at least the surface portions of the ion sources 220, 240, 250 be composed of the refractory metal rather than copper. It is also appreciated that these ion sources 220, 240, 250 may be formed in an annular shape to both provide azimuthal uniformity and to allow a plasma ring to form.

Oblique ion milling provides a new tool at controlling the sputtering profile into challenging geometries. Ion sources may be specially designed for semiconductor processing reactors to provide superior performance and fabricational results.

1. A sputter reactor, comprising:
a plasma reactor chamber arranged around a central axis to which a sputtering target can be affixed and including a pedestal electrode in opposition to said target along said central axis for supporting on a surface extending perpendicularly to said central axis a substrate to be sputter coated with material of said target, no collimator being disposed between said target and said pedestal electrode; and
a source of ions arranged along a wall of said chamber and producing a beam of particles incident upon said substrate and inclined with respect to said surface at an angle of no more than 35°.

2. The reactor of claim 1, wherein said source of ions includes a plurality of sources arranged around said central axis.

3. The reactor of claim 1, wherein said source of ions is an annular source extending around said central axis.

4. The reactor of claim 1, wherein said ions comprise argon ions and said target is a copper target.

5. The reactor of claim 1, wherein said angle is at least 10°.

6. The reactor of claim 1, wherein said ion source is capable of producing said particles with energies in a range of 200 to 1500 eV.

7. The reactor of claim 6, wherein said range extends from 400 to 1200 eV.

8. The reactor of claim 1, wherein said ion source is an anode layer source.

9. The reactor of claim 1, wherein said source is an annular source arranged around said central axis and producing an annular beam directed toward said pedestal electrode.

10. A sputter reactor, comprising:
a plasma reactor chamber arranged around a central axis to which a sputtering target can be affixed and including a pedestal electrode in opposition to said target along said central axis for supporting on a surface extending perpendicularly to said central axis a substrate to be sputter coated with a material of said target; and
a source of ions including a plasma cell including walls consisting essentially of said material and producing a beam of particles incident upon said substrate and inclined with respect to said surface at an angle of no more than 35°.

11. The reactor of claim 10, wherein said material is copper.

12. The reactor of claim 10, wherein said source is an anode layer source.

13. The reactor of claim 10, further comprising a magnet disposed outside of said cell and producing a magnetic field inside said cell to support a plasma therein.

14. The reactor of claim 10, wherein said source is an annular source producing an annular beam directed at said pedestal electrode.

15. A milling reactor, comprising:
a vacuum chamber arranged around a central axis to and including a pedestal for supporting a semiconductor wafer on a surface extending perpendicularly to said central axis a substrate; and
an annular source of ions disposed adjacent a sidewall of said chamber about said central axis and producing an annular beam of particles incident upon said wafer and inclined with respect to said surface at an angle of no more than 35°.

16. The reactor of claim 15, wherein said source of ions is an anode layer source.

17. The reactor of claim 15, wherein a target may be affixed to said vacuum chamber in opposition to said pedestal for sputter depositing a material of said target onto said wafer.

18. The reactor of claim 15, wherein said source of ions is capable of producing particles having an energy in a range of 200 to 1500 eV.

19. The reactor of claim 15, wherein said particles comprise argon.

20. A milling reactor, comprising:
a vacuum chamber arranged around a central axis to and including a pedestal in opposition to said target along said central axis for supporting a semiconductor wafer on a surface extending perpendicularly to said central axis a substrate; and
a plurality of independently controlled sources of ions disposed adjacent a sidewall of said chamber about said central axis and producing respective beams of particles incident upon said wafer and inclined with respect to said surface at differing and respective angles of no more than 35°.

21. The reactor of claim 20, wherein said sources are annular sources about said central axis.

22. The reactor of claim 20, wherein said sources are anode layer sources.

23. The reactor of claim 20, wherein a target is affixable to said vacuum chamber in opposition to said pedestal for sputter depositing a material of said target onto said wafer.

24. A method of sputtering copper into a substrate containing holes of aspect ratio of at least four, comprising:
sputtering copper onto said substrate; and
thereafter irradiating said substrate with a beam of atomic particles at an angle of no more than 35° with respect to a surface of said substrate.

25. The method of claim 24, wherein said atomic particles comprise argon.

26. The method of claim 24, wherein said atomic particles have an energy of at least 200 eV.

27. The method of claim 26, wherein said energy is less than 500 eV.

28. The method of claim 24, wherein said angle is at least 10°.

29. The method of claim 24, including a plurality of cycles of said sputtering and irradiating steps.

30. The method of claim 24, wherein said sputtering and irradiating steps are performed in different vacuum chambers.

31. An ion source, comprising:
a conductive, non-magnetic cell body having including an emission slit therethrough;
an electrode disposed within an interior of cell body;
an electrical source biasing said electrode relative to said cell body; and
a magnet disposed on a side of said electrode opposite said slit.

32. The source of claim 31, wherein said magnet comprises a plurality of separately controlled electromagnets.

33. The source of claim 31, wherein said magnet is disposed outside of said cell body.

34. The source of claim 31, wherein said cell body and said electrode principally comprise copper.

35. The source of claim 31, wherein said cell body is formed in an annulus with said slit facing a center of said annulus.

36. The source of claim 31, further comprising a source of argon into said interior.
